(19) United States
(12) Patent Application Publication
(10) Pub. No.: US 2024/0284637 A1
(43) Pub. Date: Aug. 22, 2024

(54) HEAT SINK

(71) Applicant: Furukawa Electric Co., Ltd., Tokyo (JP)

(72) Inventors: Yoshikatsu INAGAKI, Tokyo (JP); Yasuhiro UCHIMURA, Tokyo (JP)

(73) Assignee: Furukawa Electric Co., Ltd., Tokyo (JP)

(21) Appl. No.: 18/653,352

(22) Filed: May 2, 2024

Related U.S. Application Data
(63) Continuation of application No. PCT/JP2022/018183, filed on Apr. 19, 2022.

(30) Foreign Application Priority Data
Dec. 16, 2021 (JP) 2021-204621

(51) Int. Cl. H05K 7/20

(52) U.S. Cl. CPC H05K 7/2039; H05K 7/20336

(57) ABSTRACT

A heat sink including: a base portion to which a heat-generating element is thermally connected; a radiating fin provided on a front surface of the base portion; a heat pipe that is provided in an internal space of the base portion and stretches in a planar direction of the base portion; and a sealing member that is provided in the internal space of the base portion so as to face an end portion of the heat pipe in a longitudinal direction and seals the internal space of the base portion.

### CROSS REFERENCE TO RELATED APPLICATIONS

The present application is a continuation application of International Patent Application No. PCT/JP2022/018183 filed on Apr. 19, 2022, which claims the benefit of Japanese Patent Application No. 2021-204621, filed on Dec. 16, 2021. The contents of these applications are incorporated herein by reference in their entirety.

### BACKGROUND

### Technical Field

The present disclosure relates to a heat sink in which a heat pipe is provided in an internal space formed in a base portion to which a heat-generating element is thermally connected.

### Background

Heat-generating elements such as electronic components are being mounted on electronic devices at high densities due to enhancement in functionality of the electronic devices. A heat sink in which radiating fins are provided on a base portion thermally connected to heat-generating elements such as electronic components may be used as a unit configured to cool the heat-generating elements. The amount of heat generation of heat-generating elements such as electronic components is increasing due to the enhancement in functionality of electronic devices, and it is becoming increasingly important to improve the cooling performance of the heat sink.

In order to improve the cooling performance of the heat sink, it becomes necessary to improve the fin efficiency of the radiating fins provided in the heat sink. Thus, a heat pipe is being provided in the base portion of the heat sink along the planar direction of the base portion, and heat from the heat-generating elements is being transported to a region of the base portion in which the radiating fins are provided. By transporting heat from the heat-generating elements to the region of the base portion in which the radiating fins are provided with use of the heat pipe, a thermal load on the plurality of radiating fins provided in the base portion is equalized, and the fin efficiency of the radiating fins is improved.

It becomes necessary to improve the thermal connectivity between the base portion and the heat pipe when the heat pipe is provided in the base portion of the heat sink. Thus, a heat pipe as follows is proposed (Japanese Patent Laid-Open No. 2010-112656). Specifically, a groove is provided in a front surface of a base portion, a narrow width portion of which groove width is narrow is included on an opening portion side of the groove, a wide width portion of which groove width is wider than the narrow width portion is included on a groove bottom portion side of the narrow width portion, pressure is applied to the heat pipe, which is inserted into the groove and protruding from the narrow width portion, toward the groove bottom portion, and the diameter of the heat pipe in the groove width direction is deformed in an expanding manner. As a result, an outer circumferential surface of the heat pipe is pressure-welded to an inner surface of the groove and the heat pipe is joined to the groove.

Meanwhile, the heat sink is not only mounted on devices installed indoors and may be mounted on devices installed outdoors such as communication devices. However, in the heat sink of Japanese Patent Laid-Open No. 2010-112656 in which the heat pipe is joined to the groove provided in the front surface of the base portion, the heat pipe is exposed from the base portion, and corrosion occurs in a part in which a container of the heat pipe and the base portion contact each other due to moisture such as rainwater and humidity when the heat pipe is mounted on a device installed outdoors. In particular, when a metal material forming the container of the heat pipe and a metal material forming the base portion are different from each other, galvanic corrosion is facilitated by moisture such as rainwater and humidity and the container of the heat pipe easily corrodes.

In the heat sink of Japanese Patent Laid-Open No. 2010-112656 in which the heat pipe is joined to the groove provided in the front surface of the base portion, the heat pipe is exposed from the base portion, and hence there has been room for improvement in the thermal connectivity between the base portion and the heat pipe.

In order to improve the heat release characteristics and the electromagnetic wave shielding property with respect to the heat-generating elements such as electronic components, the contact property of the base portion of the heat sink may be requested to be improved with respect to an entire substrate on which heat-generating elements such as electronic components are mounted. In order to improve the contact property of the base portion with respect to the entire substrate, shapes corresponding to shapes of parts such as the heat-generating elements mounted on the substrate may be formed in the front surface of the base portion as depressions and protrusions. However, in Japanese Patent Laid-Open No. 2010-112656, the heat pipe is joined to the front surface of the base portion. Therefore, by the depressions and protrusions formed in the front surface of the base portion, the arrangement of the heat pipe is restricted, and the degree of freedom of the arrangement of the heat pipe is sacrificed.

### SUMMARY

The present disclosure is related to providing a heat sink capable of preventing corrosion from occurring in a part in which a container of a heat pipe and a base portion contact each other due to moisture such as rainwater and humidity, excellent in thermal connectivity between the base portion and the heat pipe, and improved in the degree of freedom of the arrangement of the heat pipe.

The gist of the configuration of the present disclosure is as follows.
{1} A heat sink including:
   a base portion to which a heat-generating element is thermally connected;
   a radiating fin provided on a front surface of the base portion;
   a heat pipe that is provided in an internal space of the base portion and stretches in a planar direction of the base portion; and
   a sealing member that is provided in the internal space of the base portion so as to face an end portion of the heat pipe in a longitudinal direction and seals the internal space of the base portion.
{2} The heat sink according to {1}. In the heat sink, a resin material is further interposed between the end portion of the heat pipe in the longitudinal direction and the sealing member.
{3} The heat sink according to {1} or {2}. In the heat sink, the internal space of the base portion is a hole portion that extends in the planar direction of the base portion, and the heat pipe is inserted into the hole portion.
{4} The heat sink according to {2}. In the heat sink, a place between the end portion of the heat pipe in the longitudinal direction and the sealing member is filled with the resin material.
{5} The heat sink according to {2} or {4}. In the heat sink, a place between a part of a circumferential surface of the heat pipe and an inner surface of the internal space of the base portion is filled with the resin material.
{6} The heat sink according to any one of {1} to {5}. In the heat sink, the heat pipe is fixed to the internal space of the base portion by plastically deforming the base portion.
{7} The heat sink according to any one of {1} to {6}. In the heat sink, a material of the base portion is different from a material of a container of the heat pipe.
{8} The heat sink according to any one of {1} to {7}. In the heat sink, the sealing member is metal, and a material of the sealing member is in common with a material of the base portion.
{9} The heat sink according to any one of {1} to {8}. In the heat sink, a protruding part is provided on the front surface of the base portion.
{10} The heat sink according to any one of {1} to {9}. In the heat sink, the heat pipe has a section that stretches in a planar direction of the radiating fin.
{11} The heat sink according to any one of {1} to {10}. In the heat sink, the radiating fin includes a plurality of radiating fins parallelly arranged on the front surface of the base portion, and the heat pipe has a section that stretches in an array direction of the plurality of radiating fins.
{12} The heat sink according to any one of {1} to {11}. In the heat sink, the radiating fin is provided on one surface of the base portion.
{13} The heat sink according to any one of {1} to {11}. In the heat sink, the radiating fin is provided on both surfaces of the base portion.
{14} The heat sink according to any one of {1} to {13}. In the heat sink, a ratio of a dimension of the heat pipe in a radial direction to a thickness of the base portion is 0.009 or more and 0.800 or less.
{15} The heat sink according to any one of {1} to {14}. In the heat sink, a thickness of the base portion is 8.0 mm or more and 500 mm or less.
{16} The heat sink according to any one of {1} to {15} further having a region in which a fin pitch of a plurality of the radiating fins provided on the front surface of the base portion differs.
{17} The heat sink according to any one of {1} to {16}. In the heat sink, the heat pipe includes a plurality of heat pipes provided in the longitudinal direction of the heat pipe.

In an aspect of {1} of the heat sink of the present disclosure, the internal space is formed in the base portion, and the heat pipe is provided in the internal space. Therefore, an outer circumferential surface of the heat pipe is not exposed from the front surface of the base portion.

In an aspect of {6} of the heat sink of the present disclosure, the heat pipe is fixed to the internal space of the base portion by plastically deforming the base portion, and the heat pipe does not need to be fixed to the base portion by solder joining. Therefore, a plating layer necessary for solder joining does not need to be separately formed on the outer surface of the container of the heat pipe.

According to an aspect of the heat sink of the present disclosure, by including a heat pipe that is provided in the internal space of the base portion and stretches in a planar direction of the base portion, and a sealing member that is provided in the internal space of the base portion so as to face the end portion of the heat pipe in the longitudinal direction and seals the internal space of the base portion, the sealing property with respect to the heat pipe provided in the internal space of the base portion is excellent. Therefore, in the aspect of the heat sink of the present disclosure, corrosion can be prevented from occurring in a part in which the container of the heat pipe and the base portion contact each other due to moisture such as rainwater and humidity. According to the aspect of the heat sink of the present disclosure, the heat pipe is provided in the internal space of the base portion. Therefore, the thermal connectivity between the base portion and the heat pipe is excellent, and the degree of freedom of the arrangement of the heat pipe improves.

According to the aspect of the heat sink of the present disclosure, the resin material is further interposed between the end portion of the heat pipe in the longitudinal direction and the sealing member. Therefore, the sealing property with respect to the heat pipe provided in the internal space of the base portion improves more, corrosion can be more reliably prevented from occurring in a part in which the container of the heat pipe and the base portion contact each other due to moisture such as rainwater and humidity, and the fixing property of the heat pipe in the internal space of the base portion improves.

According to the aspect of the heat sink of the present disclosure, the place between the end portion of the heat pipe in the longitudinal direction and the sealing member is filled with the resin material. Therefore, the sealing property with respect to the heat pipe provided in the internal space of the base portion further improves, and the fixing property of the heat pipe in the internal space of the base portion further improves.

When a plating layer necessary for solder joining to the base portion is formed on the outer surface of the container of the heat pipe, the corrosion resistance of the container of the heat pipe may decrease on the base portion side using aluminum, for example. Meanwhile, according to the aspect of the heat sink of the present disclosure, the heat pipe is fixed to the internal space of the base portion by plastically deforming the base portion, and the heat pipe does not need to be fixed to the base portion by solder joining. Therefore, corrosion can be more reliably prevented from occurring in a part in which the container of the heat pipe and the base portion contact each other.

According to the aspect of the heat sink of the present disclosure, the sealing property with respect to the heat pipe provided in the internal space of the base portion is excellent. Therefore, even when the material of the base portion is different from the material of the container of the heat pipe, galvanic corrosion due to moisture such as rainwater and humidity can be prevented.

According to the aspect of the heat sink of the present disclosure, the sealing member is metal, and the material of the sealing member is in common with the material of the base portion. Therefore, galvanic corrosion due to moisture such as rainwater and humidity does not occur, and corrosion can be further prevented from occurring in a part in which the container of the heat pipe and the base portion contact each other. The resin material is interposed between the end portion of the heat pipe in the longitudinal direction and the metal sealing member. Therefore, the sealing property with respect to the heat pipe provided in the internal space of the base portion improves more, and corrosion can be further reliably prevented from occurring in a part in which the container of the heat pipe and the base portion contact each other due to moisture such as rainwater and humidity.

According to the aspect of the heat sink of the present disclosure, the heat pipe has a section that stretches in the planar direction of the radiating fin. Therefore, the heat from the heat-generating element can be transported to the entirety of the radiating fin, and hence the fin efficiency of the radiating fin improves.

According to the aspect of the heat sink of the present disclosure, the radiating fin includes a plurality of radiating fins parallelly arranged on the front surface of the base portion, and the heat pipe has a section that stretches in the array direction of the plurality of radiating fins. Therefore, the heat from the heat-generating element can be transported to the plurality of radiating fins, and hence the fin efficiency of the plurality of radiating fins improves.

According to the aspect of the heat sink of the present disclosure, the ratio of the dimension of the heat pipe in the radial direction to the thickness of the base portion is 0.10 or more and 0.80 or less. Therefore, the heat transportation characteristics of the heat pipe and the heat transfer characteristics of the base portion with respect to the radiating fin can be improved in a balanced manner.

### BRIEF DESCRIPTION OF THE DRAWINGS

FIG. 1 is a perspective view describing a heat sink according to a first embodiment of the present disclosure;

FIG. 2 is a perspective view describing a heat sink according to a second embodiment of the present disclosure;

FIG. 3 is a perspective view describing a heat sink according to a third embodiment of the present disclosure;

FIG. 4 is a perspective view describing a heat sink according to a fourth embodiment of the present disclosure;

FIG. 5 is a plan view describing a heat sink according to a fifth embodiment of the present disclosure;

FIG. 6 is a front view describing the heat sink according to the fifth embodiment of the present disclosure;

FIG. 7 is a bottom view describing the heat sink according to the fifth embodiment of the present disclosure;

FIG. 8 is a perspective view describing the heat sink according to the fifth embodiment of the present disclosure;

FIG. 9 is a side cross-sectional view describing the heat sink according to the fifth embodiment of the present disclosure;

FIG. 10 is a cross-sectional view describing a heat sink according to a sixth embodiment of the present disclosure;

FIG. 11 is a cross-sectional view describing a heat sink according to a seventh embodiment of the present disclosure;

FIG. 12 is a perspective view describing a heat sink according to an eighth embodiment of the present disclosure;

FIG. 13 is a perspective view describing a heat sink according to a ninth embodiment of the present disclosure from the rear direction;

FIG. 14 is a perspective view describing the heat sink according to the ninth embodiment of the present disclosure from the front direction;

FIG. 15 is a perspective view describing a heat sink according to a tenth embodiment of the present disclosure;

FIG. 16A is an explanatory view of a base portion in a manufacturing method example of the heat sink of the present disclosure, and FIG. 16B is a cross-sectional view taken along line A-A in FIG. 16A;

FIG. 17 is an explanatory view of a heat pipe insertion step in the manufacturing method example of the heat sink of the present disclosure;

FIG. 18 is a partially enlarged view of the heat pipe insertion step in the manufacturing method example of the heat sink of the present disclosure;

FIG. 19 is a partially enlarged view of a plastic deformation step in the manufacturing method example of the heat sink of the present disclosure;

FIG. 20 is a partially enlarged view of a resin material charging step in the manufacturing method example of the heat sink of the present disclosure;

FIG. 21 is a partially enlarged view of a sealing step in the manufacturing method example of the heat sink of the present disclosure; and

FIG. 22 is a partially enlarged view after the end of the sealing step in the manufacturing method example of the heat sink of the present disclosure.

### DETAILED DESCRIPTION

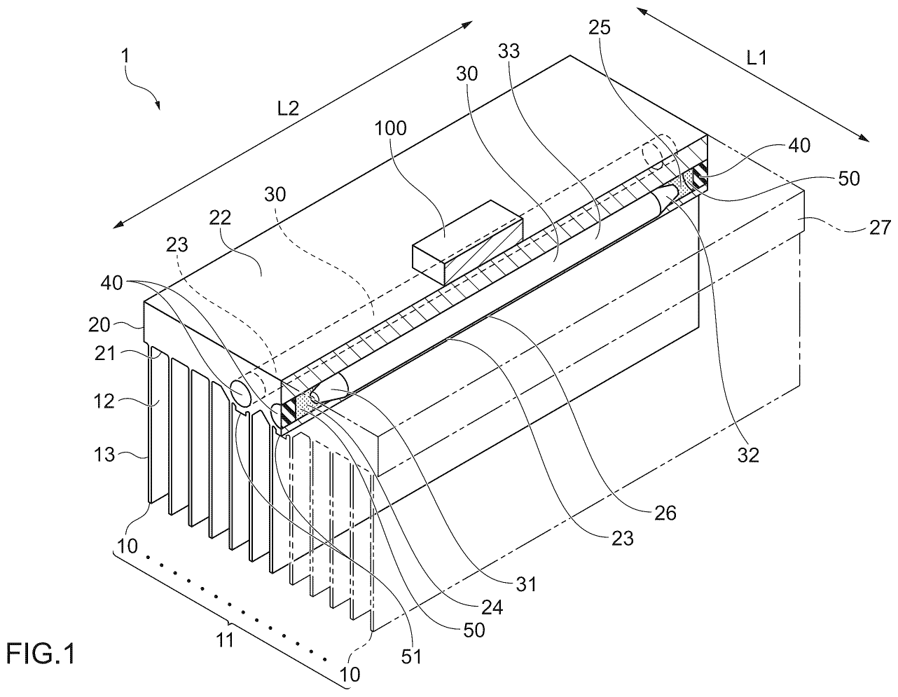

Hereinafter, a heat sink according to a first embodiment of the present disclosure will be described with reference to the accompanying drawings. FIG. 1 is a perspective view describing the heat sink according to the first embodiment of the present disclosure.

As illustrated in FIG. 1, a heat sink 1 according to the first embodiment includes a base portion 20 having a flat-plate-like shape, a plurality of radiating fins 10, 10, 10 . . . provided on a front surface of the base portion 20, and heat pipes 30 that are provided in internal spaces 23 of the base portion 20 and stretch in the planar direction of the base portion 20. The heat pipe 30 is provided in the internal space 23 of the base portion 20, and hence the heat pipe 30 is thermally connected to the base portion 20. The radiating fins 10 are provided on a first front surface 21 of the base portion 20, and hence the radiating fins 10 are thermally connected to the base portion 20.

The base portion 20 is a plate-like section having a first direction L1 and a second direction L2 orthogonal to the first direction L1. The shape of the base portion 20 is not particularly limited but is a quadrilateral shape in planar view (a state visually recognized from a position facing the radiating fins 10) in the heat sink 1 for explanatory convenience. The base portion 20 includes the first front surface 21 that is a planar surface and a second front surface 22 that is a planar surface facing the first front surface 21. The plurality of radiating fins 10, 10, 10 . . . are provided on the first front surface 21 of the base portion 20, and a heat-generating element 100 that is a cooling target of the heat sink 1 is thermally connected to the second front surface 22 of the base portion 20. The heat-generating element 100 abuts against the second front surface 22 of the base portion 20, and hence the base portion 20 is thermally connected to the heat-generating element 100. Therefore, the second front surface 22 of the base portion 20 functions as a heat receiving surface.

The base portion 20 is formed by a thermally conductive member. As the thermally conductive member, metal members of copper, copper alloy, aluminum, and aluminum alloy, for example, can be listed.

The plurality of radiating fins 10, 10, 10 . . . in plate-like shapes are erected on the base portion 20. The radiating fins 10 are erected on the first front surface 21 of the base portion 20 at a predetermined angle with respect to the extending direction of the first front surface 21. In the heat sink 1, the radiating fins 10 are erected in a substantially vertical direction with respect to the extending direction of the first front surface 21. The radiating fins 10 extend from one end to another end of the base portion 20 in the second direction L2. The radiating fins 10 are substantially the same height from one end to the other end of the base portion 20 in the second direction L2.

The plurality of radiating fins 10, 10, 10 . . . are parallelly arranged on the first front surface 21 of the base portion 20 and form a radiating fin group 11. In the heat sink 1, the plurality of radiating fins 10, 10, 10 . . . are parallelly arranged from one end to another end of the base portion 20 in the first direction L1 and form a radiating fin group 11. The fin pitch of the plurality of radiating fins 10, 10, 10 . . . is not particularly limited, and the plurality of radiating fins 10, 10, 10 . . . are parallelly arranged at substantially even intervals across the entire radiating fin group 11 in the heat sink 1.

The radiating fins 10 are not provided on the second front surface 22 of the base portion 20. Therefore, the radiating fins 10 are provided on one surface of the base portion 20. The radiating fins 10 have thin flat-plate-like shapes and each has a main front surface 12 and a side surface 13. In the radiating fin 10, the main front surface 12 mainly contributes to the heat release of the radiating fin 10. The width of the side surface 13 forms the thickness of the radiating fin 10.

The quality of material of the radiating fins 10 is not particularly limited and copper, copper alloy, aluminum, and aluminum alloy, for example, can be listed. As the quality of material of the radiating fins 10, the same quality of material as the base portion 20 can be listed. The radiating fins 10 may be integrally formed with the base portion 20 or may be members that are bodies separate from the base portion 20, but it is preferred that the radiating fins 10 be integrally formed with the base portion 20 in terms of mechanical strength, thermally conductivity, reduction in the number of parts, ease of quality management, reduction of manufacturing cost, and the like.

As illustrated in FIG. 1, the internal space 23 is formed in the base portion 20. The internal space 23 of the base portion 20 is a hole portion that extends in the planar direction of the base portion 20 and is formed in a predetermined position in a side surface 27 forming the thickness direction of the base portion 20. From the above, the internal space 23 of the base portion 20 is provided in a position spaced apart from the first front surface 21 and the second front surface 22 by a predetermined distance. Therefore, the internal space 23 is embedded in the base portion 20. In the heat sink 1, the internal space 23 extends along the extending direction of the radiating fins 10, in other words, along the second direction L2 of the base portion 20. The internal space 23 is a through hole that passes through the base portion 20. The shape and the size of the internal space 23 that is the hole portion in the radial direction correspond to the shape and the size of the heat pipe 30 in the radial direction, and the heat pipe 30 is inserted into the internal space 23. The heat pipe 30 is provided in the internal space 23 formed in the base portion 20, and hence the heat pipe 30 is embedded in the base portion 20. An outer circumferential surface of the heat pipe 30 is not exposed from the first front surface 21 and the second front surface 22 of the base portion 20.

The heat pipe 30 has a container 33 having a pipe-like shape in which an end surface of one end portion 31 and an end surface of another end portion 32 are sealed, a wicked structure (not shown) having a capillary force accommodated in the container 33, and working fluid (not shown) such as water enclosed in the internal space of the container 33. The container 33 is a pipe material of which internal space is caused to be airtight. The internal space of the container 33 is depressurized by deaeration processing. In the heat sink 1, the shape of the container 33 in the longitudinal direction is substantially linear. The shape of the container 33 in a direction (radial direction) orthogonal to the longitudinal direction is not particularly limited and is a circular shape, an elliptical shape, a flat shape, a rectangular shape, or the like. In the heat sink 1, the shape of the container 33 is a circular shape for explanatory convenience. In correspondence to the shape of the container 33 in the longitudinal direction and the shape of the container 33 in the radial direction, the shape of the internal space 23 of the base portion 20 in the longitudinal direction is substantially linear, and the shape of the internal space 23 in a direction (radial direction) orthogonal to the longitudinal direction is a circular shape.

In the heat sink 1, in correspondence to the internal space 23 extending along the planar direction of the main front surfaces 12 of the radiating fins 10, the heat pipe 30 stretches in the planar direction of the radiating fins 10. In other words, the longitudinal direction of the heat pipe 30 stretches along the second direction L2 of the base portion 20. In the heat sink 1, a plurality of the internal spaces 23, 23, 23 . . . are parallelly arranged along the first direction L1 of the base portion 20, and the heat pipe 30 is provided in each of the plurality of internal spaces 23, 23, 23. . . . Therefore, the plurality of heat pipes 30, 30, 30 . . . are parallelly arranged in a state in which the outer circumferential surfaces of the heat pipe 30 face each other in the direction of the first direction L1 of the base portion 20.

The heat pipe 30 is fixed to the internal space 23 of the base portion 20 by plastically deforming the base portion 20. From the above, the heat pipe 30 does not need to be fixed to the base portion 20 by solder joining. Therefore, a plating layer necessary for solder joining does not need to be separately formed on an outer surface of the container 33 of the heat pipe 30.

The base portion 20 is pressed in the direction of the heat pipe 30 by a pressing jig from a place on the first front surface 21 or the second front surface 22 of the base portion 20 to the heat pipe 30 inserted into the internal space 23, and the base portion 20 is plastically deformed. As a result of the base portion 20 being plastically deformed as described above, the heat pipe 30 is pressed in a pressing direction (in other words, a swaging direction) and is expanded in diameter in a direction orthogonal to the swaging direction. As a result, the heat pipe 30 is pressure-welded to the internal space 23, and the heat pipe 30 is swaged and fixed to the internal space 23 of the base portion 20. Only sections in which the heat pipe 30 contacts the internal space 23 are preferred as plastically deformed sections of the base portion 20 in terms of facilitating the insertion of the sealing member 40 described below. In other words, it is preferred that one end 24 and the other end 25 of the internal space 23 into which the sealing member 40 is inserted are not plastically deformed.

When the base portion 20 is pressed from a place on the front surface of the base portion 20, protruding parts 51 may be provided on the front surface of the base portion 20. When the base portion 20 is pressed from a place on the first front surface 21 of the base portion 20, each protruding part 51 may be provided between the radiating fin 10 and the radiating fin 10 in the first front surface 21 of the base portion 20. When the base portion 20 is pressed from a place on the second front surface 22 of the base portion 20, each protruding part 51 may be provided on the second front surface 22. As a result of the protruding part 51 being provided on the front surface of the base portion 20, by pressing the protruding part 51 by the pressing jig, the plastic deformation of the base portion 20 can be simplified and the fixing property of the heat pipe 30 with respect to the base portion 20 improves. In the heat pipe 30, the protruding part 51 is provided between the radiating fin 10 and the radiating fin 10 on the first front surface 21 of the base portion 20.

The material of container 33 of the heat pipe 30 may be the same to or different from the material of the base portion 20. As the material of the container 33 of the heat pipe 30, copper, copper alloy, aluminum, aluminum alloy, titanium, titanium alloy, and stainless steel, for example, can be listed.

As illustrated in FIG. 1, the length of the heat pipe 30 is shorter than the length of the internal space 23, the heat pipe 30 exists in a central portion 26 of the internal space 23, and the heat pipe 30 does not stretch to one end 24 and the other end 25 of the internal space 23. Therefore, the heat pipe 30 does not exist in one end 24 and the other end 25 of the internal space 23. The sealing member 40 is inserted into one end 24 and the other end 25 of the internal space 23 of the base portion 20. In other words, the sealing member 40 that seals the internal space 23 of the base portion 20 is provided in one end 24 and the other end 25 of the internal space 23 of the base portion 20 so as to face one end portion 31 and the other end portion 32 of the heat pipe 30 in the longitudinal direction.

The sealing member 40 is a lid body inserted into each of one end 24 and the other end 25 of the internal space 23. One end 24 of the internal space 23 is sealed as a result of the sealing member 40 being fitted into one end 24 of the internal space 23. The other end 25 of the internal space 23 is sealed as a result of the sealing member 40 being fitted into the other end 25 of the internal space 23. The internal space 23 becomes a sealed space caused to be airtight by sealing one end 24 of the internal space 23 by the sealing member 40 and sealing the other end 25 of the internal space 23 by the sealing member 40.

An outer end surface of the sealing member 40 may be positioned on the same planar surface as the side surface 27 forming the thickness direction of the base portion 20. For example, the outer end surface of the sealing member 40 and the side surface 27 forming the thickness direction of the base portion 20 can be on the same planar surface by cutting and processing an end portion of the sealing member 40 protruding from the side surface 27 forming the thickness direction of the base portion 20.

It is preferred that the sealing member 40 be a metal member. When the sealing member 40 is a material other than metal such as resin, there is a possibility of air bubbles remaining in sealing member 40. In low-viscosity resin in which air bubbles do not remain in the sealing member 40, there is a tendency of not having sufficient sealing property with respect to the heat pipe 30 provided in the internal space 23 of the base portion 20. As a result of the sealing member 40 being a metal member, the sealing member 40 tends to have a better sealing property with respect to the heat pipe 30 provided in the internal space 23 of the base portion 20 as compared to a case where the sealing member 40 is a material other than metal such as resin. As the material of the sealing member 40, copper, copper alloy, aluminum, aluminum alloy, titanium, titanium alloy, and stainless steel, for example, can be listed. The material of the sealing member 40 may be the same as or different from the material of the base portion 20. In the heat sink 1, the material of the sealing member 40 is in common with the material of the base portion 20. As a result of the sealing member 40 being a metal member and the material of the sealing member 40 being in common with the material of the base portion 20, the same metal is used across the entire side surface of the base portion 20. Therefore, galvanic corrosion due to moisture such as rainwater and humidity does not occur, and corrosion can be further prevented from occurring in a part in which the container of the heat pipe and the base portion contact each other. The resin material is further interposed between the end portion of the heat pipe in the longitudinal direction and the metal sealing member. Therefore, the sealing property with respect to the heat pipe 30 provided in the internal space 23 of the base portion 20 improves more, and corrosion can be further reliably prevented from occurring in a part in which the container of the heat pipe 30 and the base portion 20 contact each other due to moisture such as rainwater and humidity.

As illustrated in FIG. 21 described below, it is preferred that the end portion of the sealing member 40 on the heat pipe 30 side has a barb section. The sealing member 40 is reduced in diameter as the sealing member 40 approaches the end portion on the heat pipe 30 side but is in a shape that is widened on the end portion on the heat pipe 30 side as a result of the end portion on the heat pipe 30 side having the barb section. As a result of the end portion of the sealing member 40 on the heat pipe 30 side being in a shape having a barb, a resin material 50 described below exceeds the barb section, and the sealing property with respect to the heat pipe 30 further improves.

As illustrated in FIG. 1, the resin material 50 is further interposed between one end portion 31 of the heat pipe 30 in the longitudinal direction and the sealing member 40. In the heat sink 1, a place between one end portion 31 of the heat pipe 30 in the longitudinal direction and the sealing member 40 is filled with the resin material 50. A place between a circumferential surface of the heat pipe 30 in the vicinity of one end portion 31 and an inner surface of the internal space 23 of the base portion 20 is also filled with the resin material 50. From the above, the resin material 50 that fills a place between one end portion 31 and the sealing member 40 extends to a place between the circumferential surface of the heat pipe 30 in the vicinity of one end portion 31 and the inner surface of the internal space 23. Therefore, one end portion 31 of the heat pipe 30 in the longitudinal direction is hermetically sealed with the resin material 50.

The resin material 50 is also further interposed between the other end portion 32 of the heat pipe 30 in the longitudinal direction and the sealing member 40. In the heat sink 1, a place between the other end portion 32 of the heat pipe 30 in the longitudinal direction and the sealing member 40 is filled with the resin material 50. A place between a circumferential surface of the heat pipe 30 in the vicinity of the other end portion 32 and the inner surface of the internal space 23 of the base portion 20 is also filled with the resin material 50. From the above, the resin material 50 that fills a place between the other end portion 32 and the sealing member 40 extends to a place between the circumferential surface of the heat pipe 30 in the vicinity of the other end portion 32 and the inner surface of the internal space 23. Therefore, the other end portion 32 of the heat pipe 30 in the longitudinal direction is hermetically sealed with the resin material 50.

The resin type of the resin material 50 is not particularly limited, and moisture-curable resin, thermosetting resin, and thermoplastic resin, for example, can be listed. As moisture-curable resin, silicone resin, for example, can be listed. As the thermosetting resin, phenol resin, melamine resin, epoxy resin, and urea resin, for example, can be listed. As thermoplastic resin, polyethylene, polypropylene, polystyrene, vinyl chloride resin, fluorine-based resin, and acrylic resin, for example, can be listed. Out of the above, moisture-curable resin such as silicone resin is preferred in terms of weather resistance, corrosion resistance, and the like of the resin material 50.

The ratio of the dimension of the heat pipe 30 in the radial direction to the thickness of the base portion 20 in which the internal space 23 is provided is not particularly limited, and a lower limit value of the ratio is preferably 0.009, more preferably 0.010, and particularly preferably 0.011 in terms of reliably improving the heat transportation characteristics of the heat pipe 30. Meanwhile, an upper limit value of the ratio of the dimension of the heat pipe 30 in the radial direction to the thickness of the base portion 20 is preferably 0.800, more preferably 0.700, and particularly preferably 0.600 in terms of reliably obtaining the heat transfer characteristics of the base portion 20 with respect to the radiating fins 10. The expression of “the ratio of the dimension the heat pipe in the radial direction to the thickness of the base portion” means the ratio of an average dimension of the radial direction of the heat pipe in a direction parallel to the thickness direction of the base portion to an average thickness of the base portion at a part in which the heat pipe is fixed to the internal space of the base portion.

The thickness of the base portion 20 is not particularly limited and can be selected, as appropriate, in accordance with conditions of use and the like of the heat sink. For example, a range of 8.0 mm or more and 500 mm or less, more specifically a range of 100 mm or more and 450 mm or less, and further specifically a range of 200 mm or more and 400 mm or less can be listed. The expression of “the thickness of the base portion” means an average thickness of the base portion in a part in which the heat pipe is fixed to the internal space of the base portion.

In the heat sink 1, the heat pipe 30 that is provided in the internal space 23 of the base portion 20 and stretching in the direction of the first front surface 21 and the second front surface 22 of the base portion 20, and the sealing members 40 that are provided so as to face one end portion 31 and the other end portion 32 of the heat pipe 30 in the longitudinal direction in the internal space 23 of the base portion 20 and seal the internal space 23 of the base portion 20 are included, and hence the sealing property with respect to the heat pipe 30 embedded in the base portion 20 is excellent. Therefore, the heat sink 1 can prevent corrosion from occurring in a part in which the container 33 of the heat pipe 30 and the base portion 20 contact each other due to moisture such as rainwater and humidity, and hence is excellent in weather resistance.

In the heat sink 1, the heat pipe 30 is provided in the internal space 23 of the base portion 20, and hence it is possible to contact the inner peripheral surface of the internal space 23 of the base portion 20 across the entire outer circumferential surface of the heat pipe 30, and the thermal connectivity between the base portion 20 and the heat pipe 30 is excellent. The heat pipe 30 is provided in the internal space 23 of the base portion 20, and hence the heat sink 1 can obtain the degree of freedom of the arrangement in the heat pipe 30 even when depressions and protrusions and the like are formed in the second front surface 22 of the base portion 20 to which the heat-generating element 100 is thermally connected.

The resin material 50 is further interposed between one end portion 31 of the heat pipe 30 and the sealing member 40, and the resin material 50 is further interposed between the other end portion 32 of the heat pipe 30 and the sealing member 40. Therefore, the heat sink 1 can improve the sealing property with respect to the heat pipe 30 provided in the internal space 23 of the base portion 20 more, and more reliably prevent corrosion from occurring in a part in which the container 33 of the heat pipe 30 and the base portion 20 contact each other due to moisture such as rainwater and humidity, and the fixing property of the heat pipe 30 in the internal space 23 of the base portion 20 is improved. In particular, in the heat sink 1, places between one end portion 31 and the other end portion 32 of the heat pipe 30 and the sealing members 40 are filled with the resin material 50, and hence the sealing property with respect to the heat pipe 30 provided in the internal space 23 further improves, and the fixing property of the heat pipe 30 in the internal space 23 further improves.

When a plating layer necessary for solder joining to the base portion is formed on the outer surface of the container of the heat pipe, the corrosion resistance of the container of the heat pipe may decrease. However, in the heat sink 1, the heat pipe 30 is fixed to the internal space 23 of the base portion 20 by plastically deforming the base portion 20, and the heat pipe 30 does not need to be fixed to the base portion 20 by solder joining. Therefore, corrosion can be more reliably prevented from occurring in a part in which the container 33 of the heat pipe 30 and the base portion 20 contact each other, and the weather resistance further improves.

As above, in the heat sink 1, the sealing property with respect to the heat pipe 30 provided in the base portion 20 is excellent. Therefore, even when the material of the base portion 20 and the material of the container 33 of the heat pipe 30 are different from each other such as in a case where the material of the base portion 20 is aluminum and the material of the container 33 of the heat pipe 30 is copper, for example, galvanic corrosion due to moisture such as rainwater and humidity can be prevented.

In the heat sink 1, the heat pipe 30 stretches in the direction of the main front surfaces 12 of the radiating fins 10, and hence the heat from the heat-generating element 100 can be transported to the entirety of the radiating fins 10. Therefore, the fin efficiency of the radiating fins 10 improves.

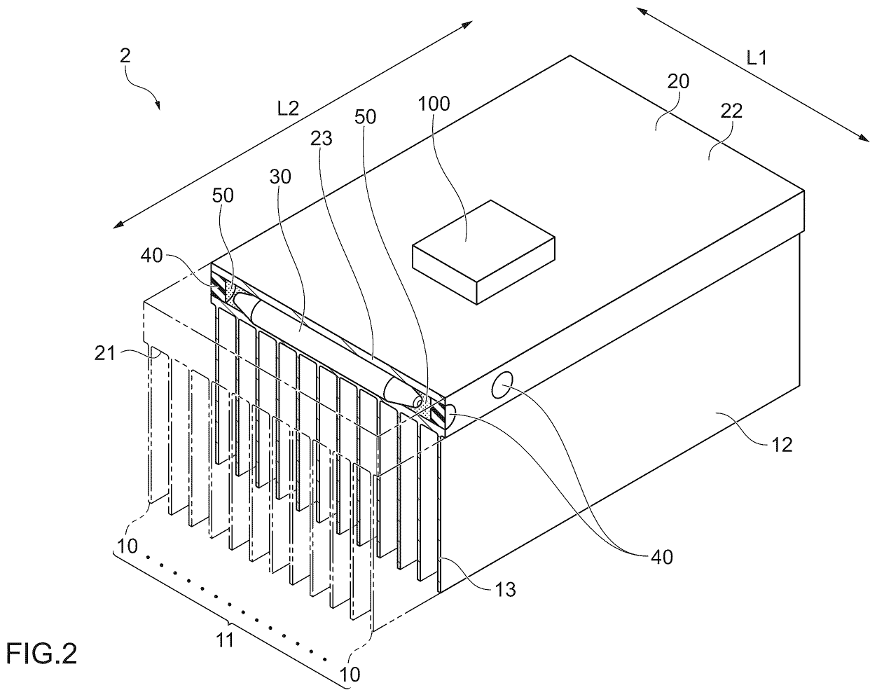

Next, a heat sink according to a second embodiment of the present disclosure will be described with reference to the accompanying drawings. The heat sink according to the second embodiment is in common with the heat sink according to the first embodiment in terms of main components, and hence the same components as those of the heat sink according to the first embodiment are described with use of the same reference characters. FIG. 2 is a perspective view describing the heat sink according to the second embodiment of the present disclosure.

In the heat sink 1 according to the first embodiment, the internal spaces 23 of the base portion 20 extend along the extending direction of the radiating fins 10, and the heat pipes 30 stretch in the direction of the main front surfaces 12 of the radiating fins 10. However, instead of the above, as illustrated in FIG. 2, in the heat sink according to the second embodiment 2, the internal spaces 23 of the base portion 20 extend along a direction in which the plurality of radiating fins 10, 10, 10 . . . are parallelly arranged, and the heat pipes 30 stretch in the arrangement direction of the plurality of radiating fins 10, 10, 10 . . . . From the above, the heat pipes 30 stretch in a direction substantially orthogonal to the main front surfaces 12 of the radiating fins 10.

Also in the heat sink 2, the heat pipe 30 that is provided in the internal space 23 of the base portion 20 and stretches in the direction of the first front surface 21 and the second front surface 22 of the base portion 20, and the sealing members 40 that seal the internal space 23 of the base portion 20 are included, and hence the sealing property with respect to the heat pipe 30 embedded in the base portion 20 is excellent. Also in the heat sink 2, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 2, as a result of the heat pipe 30 being provided in the internal space 23 of the base portion 20, the degree of freedom of the arrangement in the heat pipe 30 can be obtained even when depressions and protrusions and the like are formed in the second front surface 22 of the base portion 20.

In the heat sink 2, the plurality of radiating fins 10 are parallelly arranged on the first front surface 21 of the base portion 20, and the heat pipe 30 has a section stretching in the array direction of the plurality of radiating fins 10, 10, 10 . . . . Therefore, the heat from the heat-generating element 100 can be transported to the plurality of radiating fins 10, 10, 10 . . . , and hence the fin efficiency of the plurality of radiating fins 10, 10, 10 . . . improves.

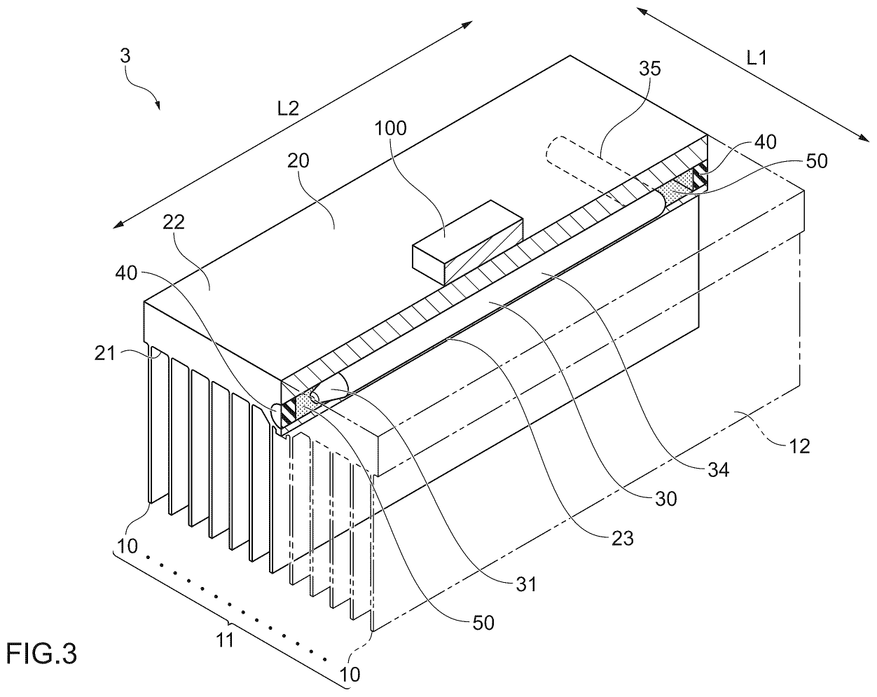

Next, a heat sink according to a third embodiment of the present disclosure will be described with reference to the accompanying drawings. The heat sink according to the third embodiment is in common with the heat sinks according to the first and second embodiments in terms of main components, and hence the same components as those of the heat sinks according to the first and second embodiments are described with use of the same reference characters. FIG. 3 is a perspective view describing the heat sink according to the third embodiment of the present disclosure.

In the heat sink 1 according to the first embodiment, the shape of the heat pipe 30 in the longitudinal direction is substantially linear. However, instead of the above, as illustrated in FIG. 3, in a heat sink 3 according to the third embodiment, the shape of the heat pipe 30 in the longitudinal direction is a shape having a bending portion and is specifically an L-like shape. Therefore, in the heat sink 3, the heat pipe 30 has a section 34 stretching in the direction of the main front surfaces 12 of the radiating fins 10, and a section 35 stretching in the arrangement direction of the plurality of radiating fins 10, 10, 10 . . . . From the above, the internal space 23 of the base portion 20 has a section stretching in the direction of the main front surfaces 12 of the radiating fins 10 and a section continuous from the section and stretching in the arrangement direction of the plurality of radiating fins 10, 10, 10 . . . .

In the heat sink 3, the sealing member 40 is provided so as to face one end portion 31 of the heat pipe 30, the sealing member 40 is provided so as to face the section 35 of the heat pipe 30 stretching in the arrangement direction of the plurality of radiating fins 10, 10, 10 . . . . A place between one end portion 31 of the heat pipe 30 and the sealing member 40 is filled with the resin material 50, and a place between the section 35 of the heat pipe 30 stretching in the arrangement direction of the plurality of radiating fins 10, 10, 10 . . . and the sealing member 40 is filled with the resin material 50.

Also in the heat sink 3, the heat pipe 30 that is provided in the internal space 23 of the base portion 20 and stretches in the direction of the first front surface 21 and the second front surface 22 of the base portion 20, and the sealing members 40 that seal the internal space 23 of the base portion 20 are included, and hence the sealing property with respect to the heat pipe 30 embedded in the base portion 20 is excellent. Also in the heat sink 3, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 3, as a result of the heat pipe 30 being provided in the internal space 23 of the base portion 20, the degree of freedom of the arrangement in the heat pipe 30 can be obtained even when depressions and protrusions and the like are formed in the second front surface 22 of the base portion 20.

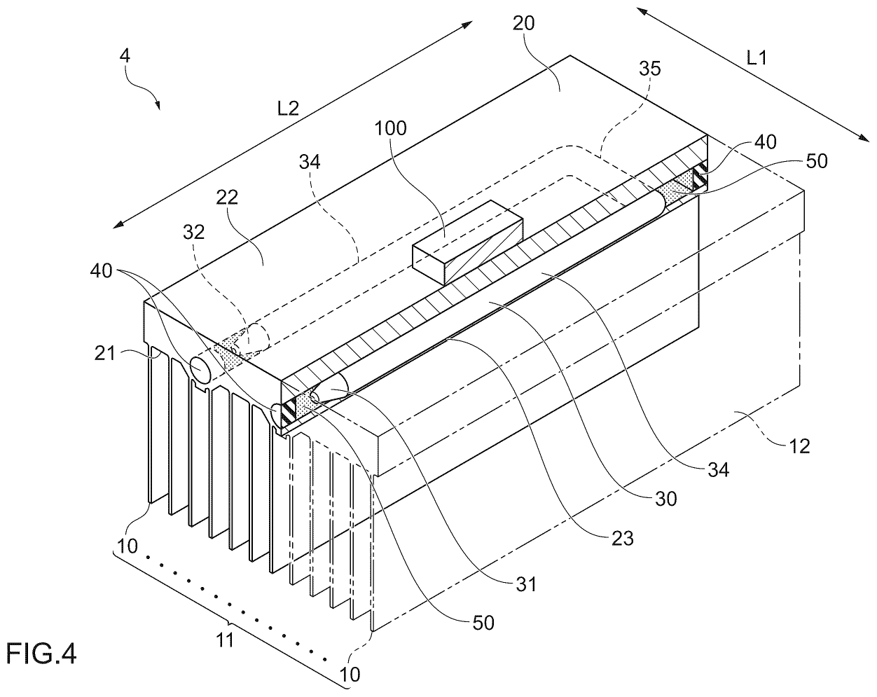

Next, a heat sink according to a fourth embodiment of the present disclosure will be described with reference to the accompanying drawings. The heat sink according to the fourth embodiment is in common with the heat sinks according to the first to third embodiments in terms of main components, and hence the same components as those of the heat sinks according to the first to third embodiments are described with use of the same reference characters. FIG. 4 is a perspective view describing the heat sink according to the fourth embodiment of the present disclosure.

In the heat sink 1 according to the first embodiment, the shape of the heat pipe 30 in the longitudinal direction is substantially linear. However, instead of the above, as illustrated in FIG. 4, in a heat sink 4 according to the fourth embodiment, the shape of the heat pipe 30 in the longitudinal direction is a shape having bending portions and is specifically a U-like shape. Therefore, in the heat sink 4, the heat pipe 30 has two sections 34 stretching in the direction of the main front surfaces 12 of the radiating fins 10, and one section 35 stretching in the arrangement direction of the plurality of radiating fins 10, 10, 10 . . . . From the above, the internal space 23 of the base portion 20 has two sections stretching in the direction of the main front surfaces 12 of the radiating fins 10 and one section continuous from the two sections and stretching in the arrangement direction of the plurality of radiating fins 10, 10, 10 . . . .

In the heat sink 4, the sealing members 40 are provided so as to face one end portion 31 and the other end portion 32 of the heat pipe 30, and the sealing members 40 are provided so as to face the section 35 of the heat pipe 30 stretching in the arrangement direction of the plurality of radiating fins 10, 10, 10. A place between one end portion 31 of the heat pipe 30 and the sealing member 40 is filled with the resin material 50, a place between the other end portion 32 of the heat pipe 30 and the sealing member 40 is filled with the resin material 50, and a place between the section 35 of the heat pipe 30 stretching in the arrangement direction of the plurality of radiating fins 10, 10, 10 . . . and the sealing members 40 is further filled with the resin material 50.

Also in the heat sink 4, the heat pipe 30 that is provided in the internal space 23 of the base portion 20 and stretches in the direction of the first front surface 21 and the second front surface 22 of the base portion 20, and the sealing members 40 that seal the internal space 23 of the base portion 20 are included, and hence the sealing property with respect to the heat pipe 30 embedded in the base portion 20 is excellent. Also in the heat sink 4, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 4, as a result of the heat pipe 30 being provided in the internal space 23 of the base portion 20, the degree of freedom of the arrangement in the heat pipe 30 can be obtained even when depressions and protrusions and the like are formed in the second front surface 22 of the base portion 20.

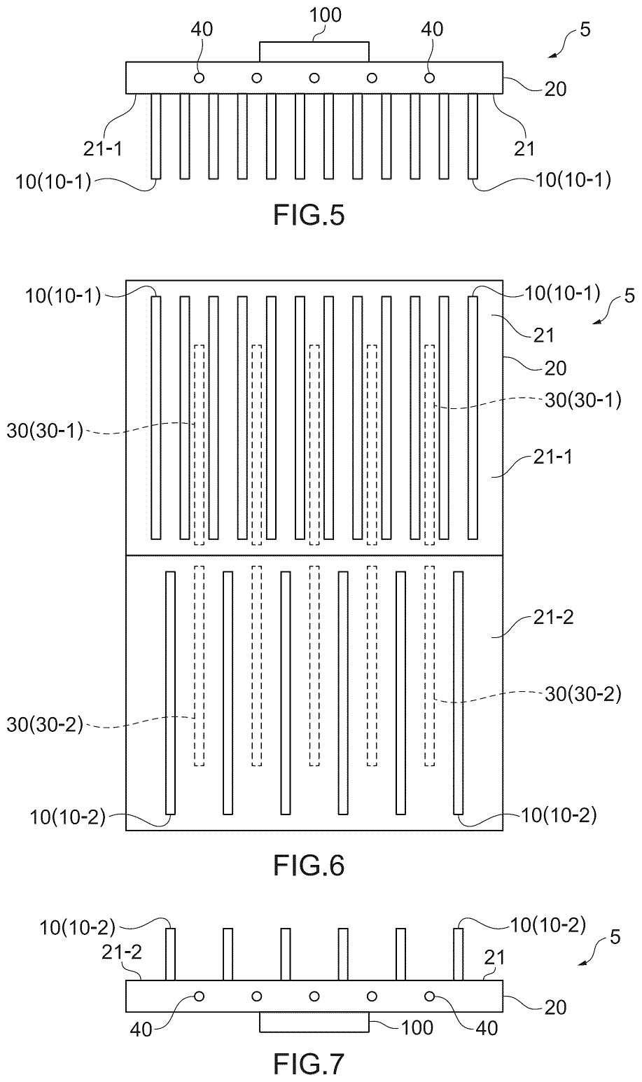

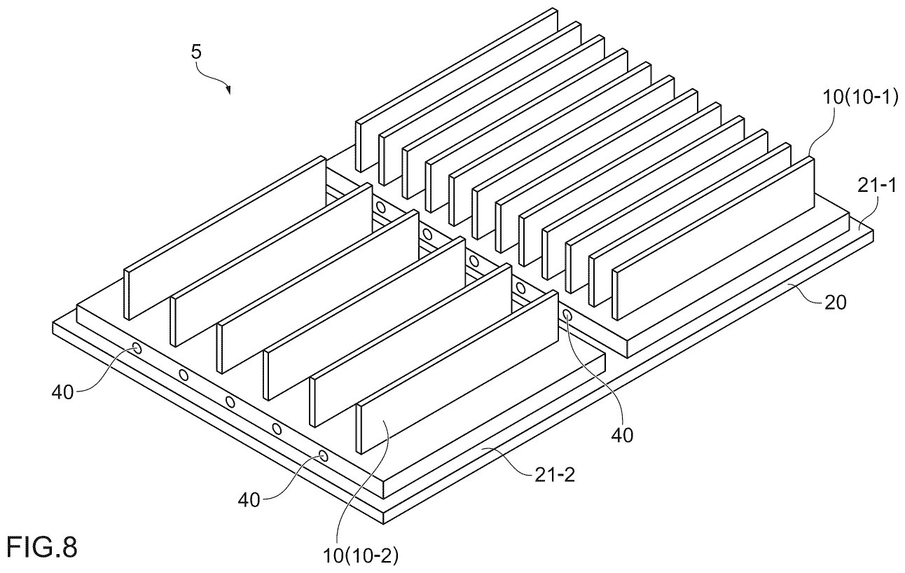

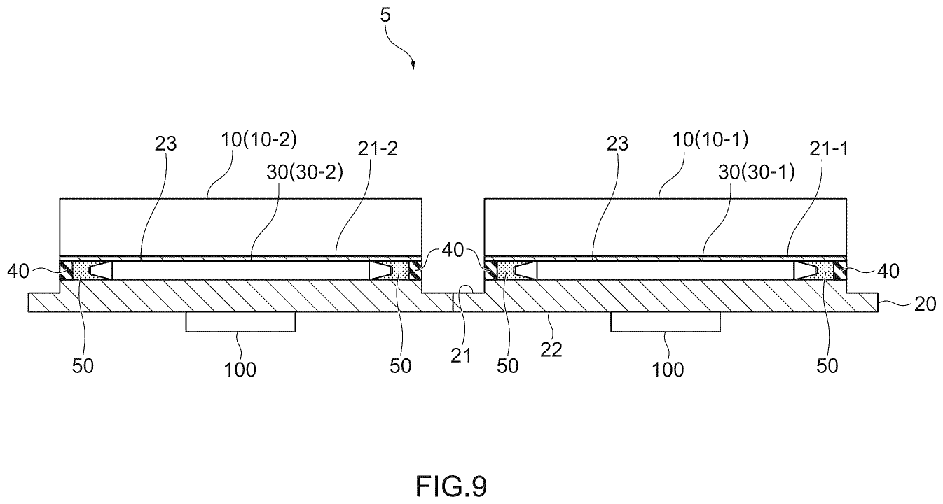

Next, a heat sink according to a fifth embodiment of the present disclosure will be described with reference to the accompanying drawings. The heat sink according to the fifth embodiment is in common with the heat sinks according to the first to fourth embodiments in terms of main components, and hence the same components as those of the heat sinks according to the first to fourth embodiments are described with use of the same reference characters. FIG. 5 is a plan view describing the heat sink according to the fifth embodiment of the present disclosure. FIG. 6 is a front view describing the heat sink according to the fifth embodiment of the present disclosure. FIG. 7 is a bottom view describing the heat sink according to the fifth embodiment of the present disclosure. FIG. 8 is a perspective view describing the heat sink according to the fifth embodiment of the present disclosure. FIG. 9 is a side cross-sectional view describing the heat sink according to the fifth embodiment of the present disclosure.

In the heat sink 1 according to the first embodiment, the fin pitch of the plurality of radiating fins 10, 10, 10 . . . is substantially the same, and the plurality of radiating fins 10, 10, 10 . . . are parallelly arranged at substantially even intervals. However, instead of the above, as illustrated in FIGS. 5 to 8, in a heat sink 5 according to the fifth embodiment, regions in which the fin pitch of the plurality of radiating fins 10, 10, 10 . . . provided in the first front surface 21 of the base portion 20 differs are included.

In the heat sink 5, the first front surface 21 has a first region 21-1 and a second region 21-2 continuous from the first region 21-1. In the first region 21-1, a plurality of first radiating fins 10-1, 10-1, 10-1 . . . are parallelly arranged. The fin pitch of the plurality of first radiating fins 10-1, 10-1, 10-1 . . . is substantially the same, and the plurality of first radiating fins 10-1, 10-1, 10-1 . . . are parallelly arranged at substantially even intervals. In the first region 21-1, first heat pipes 30-1 stretch in the planar direction of the first radiating fins 10-1.

In the second region 21-2, a plurality of second radiating fins 10-2, 10-2, 10-2 . . . different from the first radiating fins 10-1 are parallelly arranged. The fin pitch of the plurality of second radiating fins 10-2, 10-2, 10-2 . . . is substantially the same, and the plurality of second radiating fins 10-2, 10-2, 10-2 . . . are parallelly arranged at substantially even intervals. The fin pitch of the plurality of second radiating fins 10-2, 10-2, 10-2 . . . is greater than the fin pitch of the plurality of first radiating fins 10-1, 10-1, 10-1 . . . . In other words, the interval between fins of the plurality of first radiating fins 10-1, 10-1, 10-1 . . . is narrower than the interval between fins of the plurality of second radiating fins 10-2, 10-2, 10-2 . . . .

In the second region 21-2, second heat pipes 30-2 different from the first heat pipes 30-1 stretch in the planar direction of the second radiating fins 10-2. Therefore, the plurality of heat pipes 30, in other words, the first heat pipes 30-1 and the second heat pipes 30-2 are provided along the longitudinal direction of the heat pipes 30.

In the heat sink 5, by supplying cooling air in the direction of the first region 21-1 from the second region 21-2, cooling air can be smoothly supplied to the first radiating fins 10-1 of which fin pitch is small from the second radiating fins 10-2 of which fin pitch is great, and the heat release efficiency of the first radiating fins 10-1 also improves. Therefore, the radiating fins 10 in both of the first region 21-1 and the second region 21-2 can exhibit excellent heat release efficiency.

As illustrated in FIG. 9, in the heat sink 5, the sealing members 40 that seal the internal space 23 formed in the first region 21-1 of the base portion 20 are provided so as to face end portions of each first heat pipe 30-1 in the longitudinal direction, and the resin material 50 is interposed between the end portions of the first heat pipe 30-1 in the longitudinal direction and the sealing members 40. In the heat sink 5, the sealing members 40 that seal the internal space 23 formed in the second region 21-2 of the base portion 20 are provided so as to face end portions of each second heat pipe 30-2 in the longitudinal direction, and the resin material 50 is further interposed between the end portions of the second heat pipe 30-2 in the longitudinal direction and the sealing members 40. In the heat sink 5, the heat-generating elements 100 are thermally connected to the second front surface 22 corresponding to the first region 21-1 and the second front surface 22 corresponding to the second region 21-2.

Also in the heat sink 5, the heat pipe 30 that is provided in the internal space 23 of the base portion 20 and stretches in the direction of the first front surface 21 of the base portion 20, and the sealing members 40 that seal the internal space 23 of the base portion 20 are included, and hence the sealing property with respect to the heat pipe 30 embedded in the base portion 20 is excellent. Also in the heat sink 5, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 5, as a result of the heat pipe 30 being provided in the internal space 23 of the base portion 20, the degree of freedom of the arrangement in the heat pipe 30 can be obtained even when depressions and protrusions and the like are formed in the base portion 20.

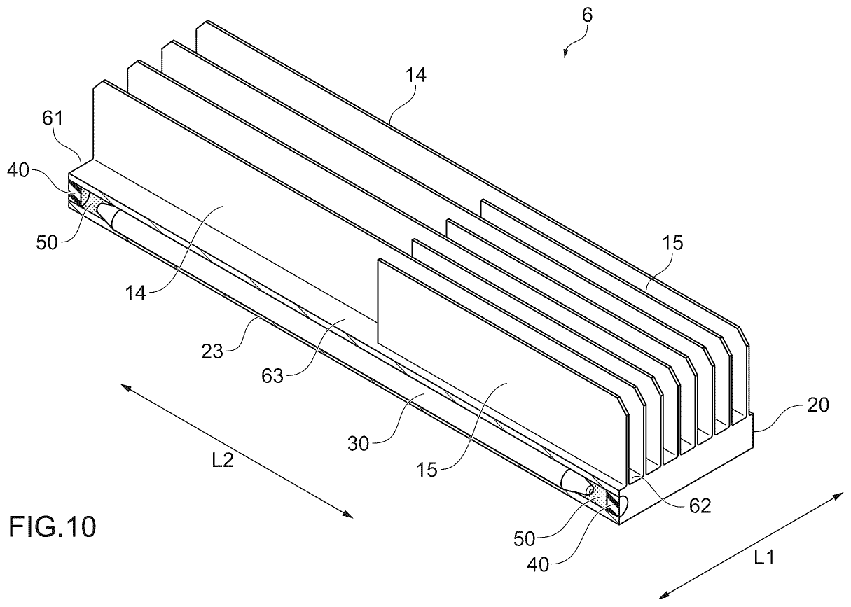

Next, a heat sink according to a sixth embodiment of the present disclosure will be described with reference to the accompanying drawings. The heat sink according to the sixth embodiment is in common with the heat sinks according to the first to fifth embodiments in terms of main components, and hence the same components as those of the heat sinks according to the first to fifth embodiments are described with use of the same reference characters. FIG. 10 is a cross-sectional view describing the heat sink according to the sixth embodiment of the present disclosure.

In the heat sink 1 according to the first embodiment, the fin pitch of the plurality of radiating fins 10, 10, 10 . . . is substantially the same, and the plurality of radiating fins 10, 10, 10 . . . are parallelly arranged at substantially even intervals. However, instead of the above, as illustrated in FIG. 10, in a heat sink 6 according to the sixth embodiment, regions in which the fin pitch of the plurality of radiating fins 10, 10, 10 . . . provided in the first front surface 21 of the base portion 20 differs are included.

In the heat sink 6, as a plurality of radiating fins, a plurality of first fin portions 14, 14, 14 . . . extending from one end 61 to another end 62 of the base portion 20 in the second direction L2, and a plurality of second fin portions 15, 15, 15 . . . extending from the other end 62 to a central portion 63 of the base portion 20 in the second direction L2 are included. The plurality of first fin portions 14, 14, 14 . . . and the plurality of second fin portions 15, 15, 15 . . . are alternately arranged from the central portion 63 to the other end 62. Therefore, the fin pitch of the radiating fins from the central portion 63 to the other end 62 of the base portion 20 is smaller than the fin pitch of the radiating fins from one end 61 to the central portion 63 of the base portion 20.

In the heat sink 6, the fin pitch of the plurality of first fin portions 14, 14, 14 . . . is substantially the same, and the fin pitch of the plurality of second fin portions 15, 15, 15 . . . is substantially the same. The fin pitch of the first fin portions 14 may be the same as the fin pitch of the second fin portions 15, may be greater the fin pitch of the second fin portions 15, or may be smaller than the fin pitch of the second fin portions 15. In the heat sink 6, the fin pitch of the first fin portions 14 is substantially the same as the fin pitch of the second fin portions 15.

Also in the heat sink 6, the heat pipe 30 that is provided in the internal space 23 of the base portion 20 and stretches in the planar direction of the base portion 20, and the sealing members 40 that seal the internal space 23 of the base portion 20 are included, and hence the sealing property with respect to the heat pipe 30 embedded in the base portion 20 is excellent. Also in the heat sink 6, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 6, as a result of the heat pipe 30 being provided in the internal space 23 of the base portion 20, the degree of freedom of the arrangement in the heat pipe 30 can be obtained even when depressions and protrusions and the like are formed in the base portion 20.

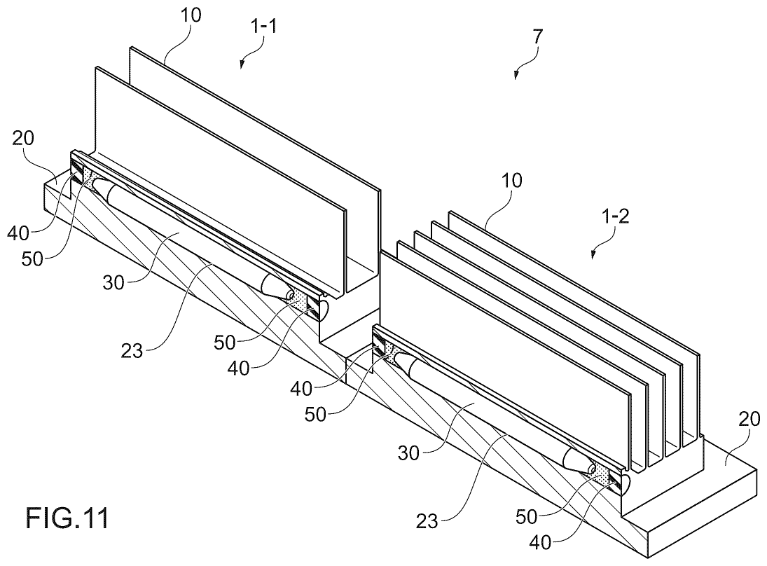

Next, a heat sink according to a seventh embodiment of the present disclosure will be described with reference to the accompanying drawings. The heat sink according to the seventh embodiment is in common with the heat sinks according to the first to sixth embodiments in terms of main components, and hence the same components as those of the heat sinks according to the first to sixth embodiments are described with use of the same reference characters. FIG. 11 is a cross-sectional view describing the heat sink according to the seventh embodiment of the present disclosure.

As illustrated in FIG. 11, in a heat sink 7 according to the seventh embodiment, a heat sink composite in which a plurality of heat sinks are parallelly arranged along the planar direction of the radiating fins 10 and the longitudinal direction of the heat pipes 30 is provided. In the heat sink 7, two heat sinks 1-1, 1-2 having structures similar to that of the heat sink 1 according to the first embodiment are parallelly arranged.

The fin pitch of the radiating fins 10 of the heat sink 1-1 may be the same or different from the fin pitch of the radiating fins 10 of the heat sink 1-2. The number of installations of the radiating fins 10 of the heat sink 1-1 may be the same or different from the number of installations of the radiating fins 10 of the heat sink 1-2. In the heat sink 7, an aspect in which the fin pitch of the radiating fins 10 of the heat sink 1-1 is greater than the fin pitch of the radiating fins 10 of the heat sink 1-2, and the number of installations of the radiating fins 10 of the heat sink 1-1 is smaller than the number of installations of the radiating fins 10 of the heat sink 1-2 is obtained. In the heat sink 7, by supplying cooling air in the direction of the heat sink 1-2 from the heat sink 1-1, cooling air can be smoothly supplied to the radiating fins 10 of the heat sink 1-2 of which fin pitch is small from the radiating fins 10 of the heat sink 1-1 of which fin pitch is great, and the heat release efficiency of the radiating fins 10 of the heat sink 1-2 also improves.

Also in the heat sink 7 that is a composite of a plurality of heat sinks, the heat pipe 30 that is provided in the internal space 23 of the base portion 20 and stretches in the planar direction of the base portion 20, and the sealing members 40 that seal the internal space 23 of the base portion 20 are included, and hence the sealing property with respect to the heat pipe 30 embedded in the base portion 20 is excellent. Also in the heat sink 7, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 7, as a result of the heat pipe 30 being provided in the internal space 23 of the base portion 20, the degree of freedom of the arrangement in the heat pipe 30 can be obtained even when depressions and protrusions and the like are formed in the base portion 20.

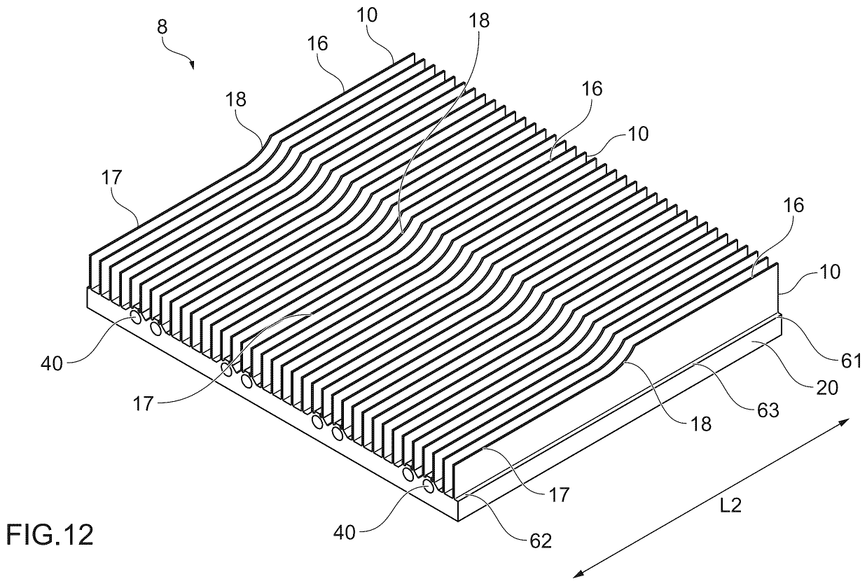

Next, a heat sink according to an eighth embodiment of the present disclosure will be described with reference to the accompanying drawings. The heat sink according to the eighth embodiment is in common with the heat sinks according to the first to seventh embodiments in terms of main components, and hence the same components as those of the heat sinks according to the first to seventh embodiments are described with use of the same reference characters. FIG. 12 is a perspective view describing the heat sink according to the eighth embodiment of the present disclosure.

In the heat sink 1 according to the first embodiment, the radiating fins 10 have substantially the same height regardless of position. However, instead of the above, as illustrated in FIG. 12, in a heat sink 8 according to the eighth embodiment, the radiating fins 10 have different heights at a position of one end 61 and a position of the other end 62 of the base portion 20.

In the heat sink 8, the radiating fins 10 extend from one end 61 to the other end 62 of the base portion 20 in the second direction L2, and the height at one end portion 16 positioned on one end 61 of the base portion 20 is higher than the height at another end portion 17 positioned on the other end 62 of the base portion 20. In the radiating fin 10, a step portion 18 is provided between one end portion 16 and the other end portion 17, and the height of the radiating fins 10 differs after the step portion 18. The radiating fins 10 have substantially the same height from one end portion 16 to the step portion 18 positioned in the central portion 63 of the base portion 20 and have substantially the same height from the step portion 18 to the other end portion 17.

In the heat sink 8, by supplying cooling air in the direction of one end portion 16 from the other end portion 17 of each of the radiating fins 10, cooling air can be smoothly supplied to the entirety of the radiating fins 10, and the fin efficiency improves.

Also in the heat sink 8 in which the height of the radiating fins 10 differs, effects similar to those of the heat sink 1 according to the first embodiment in which the height of the radiating fins 10 is substantially the same can be exhibited.

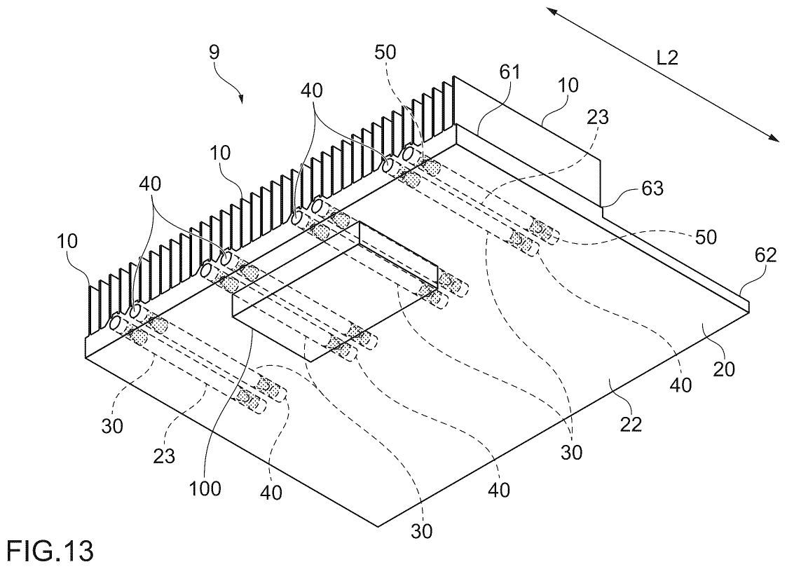

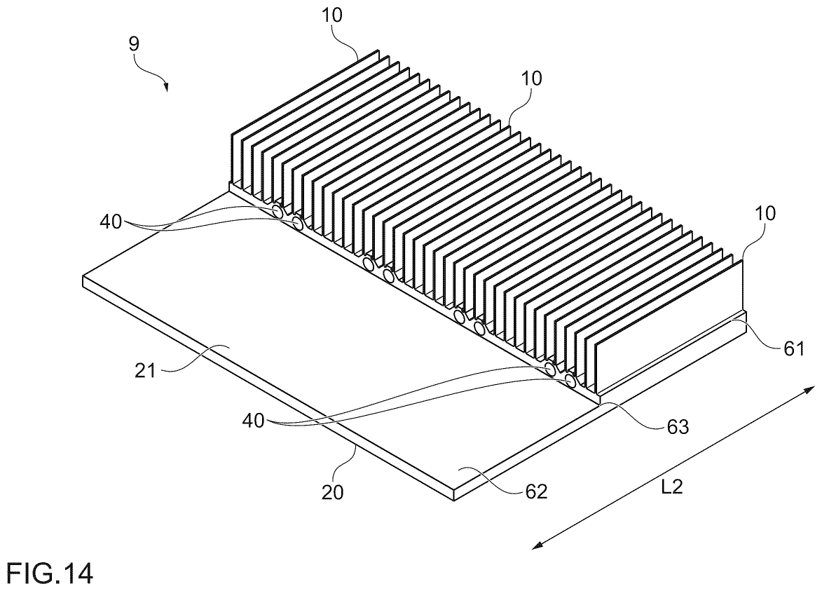

Next, a heat sink according to a ninth embodiment of the present disclosure will be described with reference to the accompanying drawings. The heat sink according to the ninth embodiment is in common with the heat sinks according to the first to eighth embodiments in terms of main components, and hence the same components as those of the heat sinks according to the first to eighth embodiments are described with use of the same reference characters. FIG. 13 is a perspective view describing the heat sink according to the ninth embodiment of the present disclosure from the rear direction. FIG. 14 is a perspective view describing the heat sink according to the ninth embodiment of the present disclosure from the front direction.

In the heat sink 1 according to the first embodiment, the radiating fins 10 extend from one end to the other end of the base portion 20 in the second direction L2. However, instead of the above, as illustrated in FIGS. 13 and 14, in a heat sink 9 according to the ninth embodiment of the present disclosure, the radiating fins 10 extend from one end 61 to the central portion 63 of the base portion 20 and the radiating fins 10 do not extend from the central portion 63 to the other end 62 out of one end 61 to the other end 62 of the base portion 20 in the second direction L2.

In the heat sink 1 according to the first embodiment, the heat pipes 30 extend from the vicinity of one end to the vicinity of the other end of the base portion 20 in the second direction L2. However, instead of the above, as illustrated in FIGS. 13 and 14, in the heat sink 9, as with the radiating fins 10, the heat pipes 30 extend from one end 61 to the central portion 63 of the base portion 20, and the heat pipes 30 do not extend from the central portion 63 to the other end 62 out of one end 61 to the other end 62 of the base portion 20 in the second direction L2. Therefore, out of one end 61 to the other end 62 of the base portion 20, the heat pipes 30 are embedded from one end 61 to the central portion 63. In the heat sink 9, the heat-generating element 100 is thermally connected to a region from one end 61 to the central portion 63 of the base portion 20 in which the radiating fins 10 and the heat pipes 30 are provided.

Also in the heat sink 9, the heat pipe 30 that is provided in the internal space 23 of the base portion 20 and stretches in the planar direction of the base portion 20, and the sealing members 40 that seal the internal space 23 of the base portion 20 are included, and hence the sealing property with respect to the heat pipe 30 embedded in the base portion 20 is excellent. Also in the heat sink 9, as a result of the heat pipe 30 being provided in the internal space 23 of the base portion 20, it is possible to contact the inner peripheral surface of the internal space 23 of the base portion 20 across the entire outer circumferential surface of the heat pipe 30, and the thermal connectivity between the base portion 20 and the heat pipe 30 is excellent. Also in the heat sink 9, as a result of the heat pipe 30 being provided in the internal space 23 of the base portion 20, the degree of freedom of the arrangement in the heat pipe 30 can be obtained even when depressions and protrusions and the like are formed in the base portion 20.

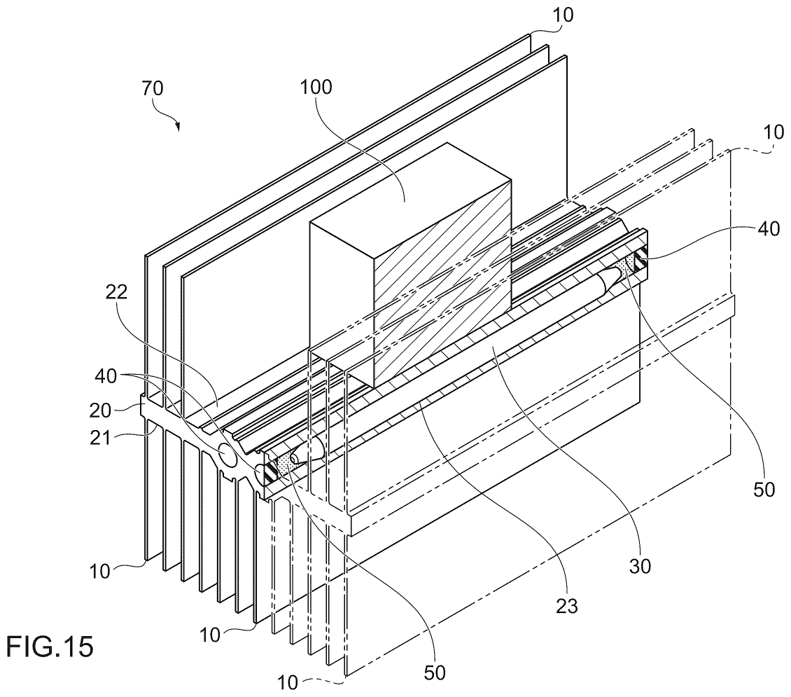

Next, a heat sink according to a tenth embodiment of the present disclosure will be described with reference to the accompanying drawings. The heat sink according to the tenth embodiment is in common with the heat sinks according to the first to ninth embodiments in terms of main components, and hence the same components as those of the heat sinks according to the first to ninth embodiments are described with use of the same reference characters. FIG. 15 is a perspective view describing the heat sink according to the tenth embodiment of the present disclosure.

In the heat sink 1 according to the first embodiment, the plurality of radiating fins 10, 10, 10 . . . are provided on the first front surface 21 of the base portion 20, and the radiating fins 10 are not provided on the second front surface 22 of the base portion 20. However, instead of the above, as illustrated in FIG. 15, in a heat sink 70 according to the tenth embodiment, the plurality of radiating fins 10, 10, 10 . . . are provided on the first front surface 21 of the base portion 20, and the plurality of radiating fins 10, 10, 10 . . . are also provided on the second front surface 22 of the base portion 20. Therefore, in the heat sink 70, the radiating fins 10 are provided on both surfaces of the base portion 20. On the second front surface 22, there is a region in which the radiating fins 10 are not provided, and the heat-generating element 100 is thermally connected to the region on the second front surface 22 in which the radiating fins 10 are not provided. As above, in the heat sink of the present disclosure, the radiating fins 10 can be provided on one surface or both surfaces of the base portion 20 in accordance with the conditions of use and the like.

In the heat sink 70, the radiating fins 10 are provided on both surfaces of the base portion 20, and hence the heat release characteristics further improve.

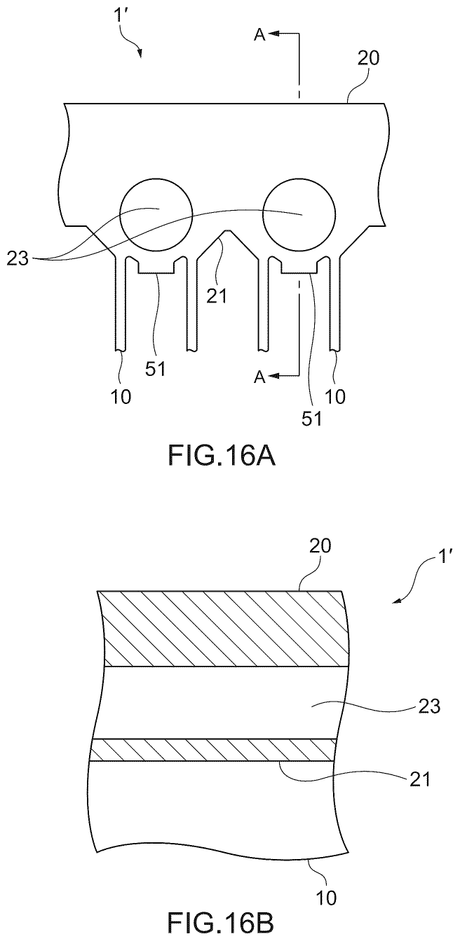

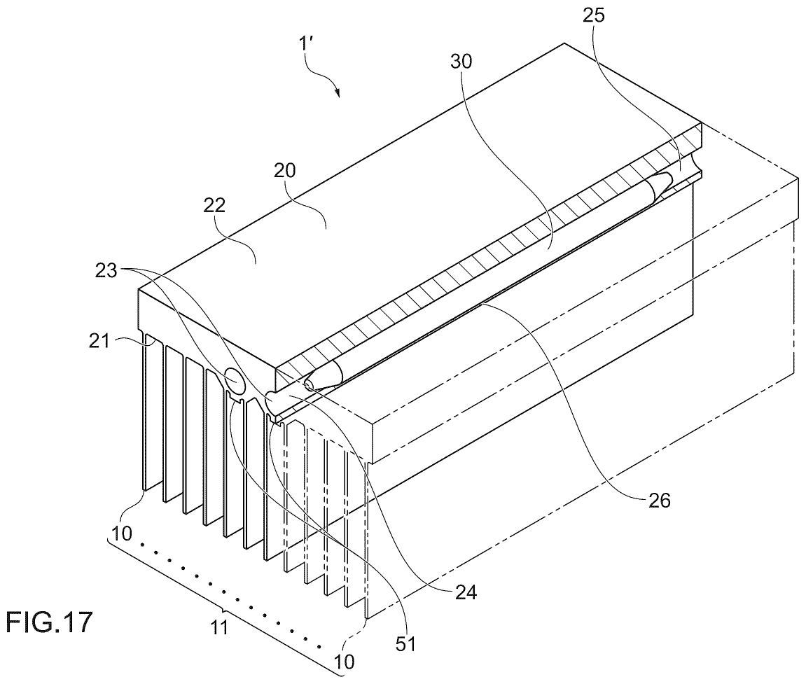

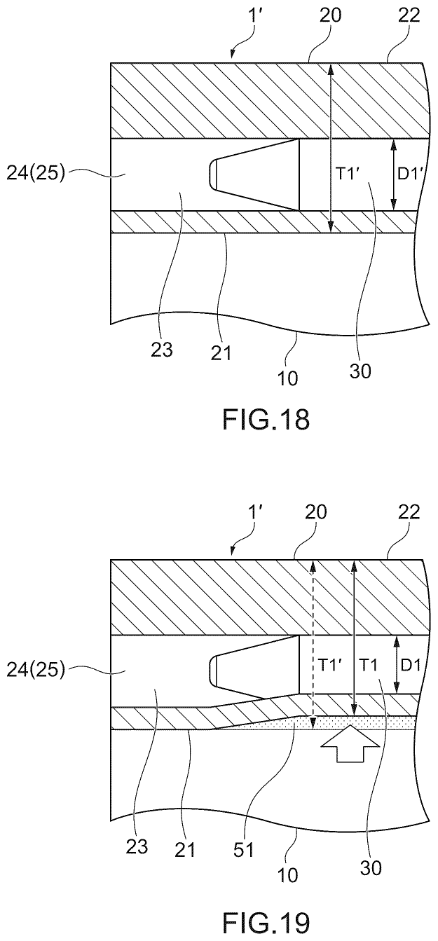

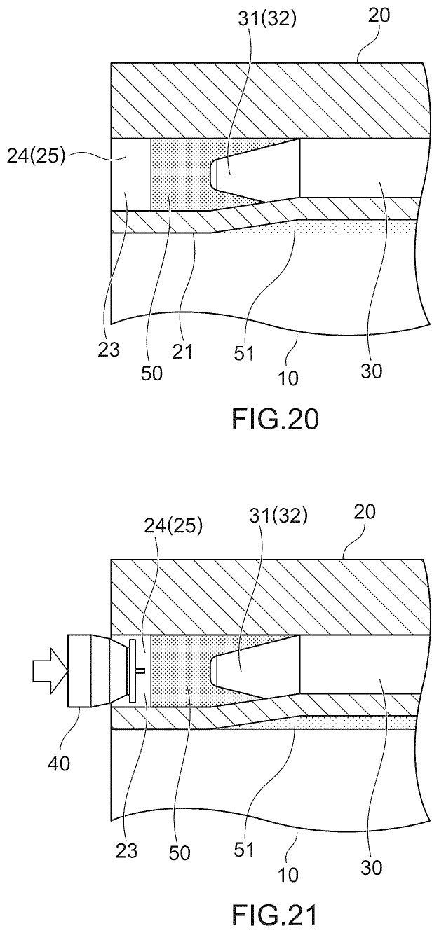

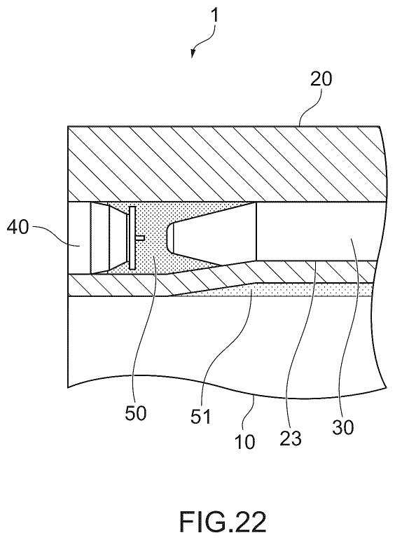

Next, a manufacturing method example of the heat sink of the present disclosure will be described with reference to the accompanying drawings. Here, the manufacturing method example of the heat sink is described with use of the heat sink 1 according to the first embodiment. FIG. 16A is an explanatory view of the base portion in the manufacturing method example of the heat sink of the present disclosure, and FIG. 16B is a cross-sectional view taken along line A-A in FIG. 16A. FIG. 17 is an explanatory view of a heat pipe insertion step in the manufacturing method example of the heat sink of the present disclosure. FIG. 18 is a partially enlarged view of the heat pipe insertion step in the manufacturing method example of the heat sink of the present disclosure. FIG. 19 is a partially enlarged view of a plastic deformation step in the manufacturing method example of the heat sink of the present disclosure. FIG. 20 is a partially enlarged view of a resin material charging step in the manufacturing method example of the heat sink of the present disclosure. FIG. 21 is a partially enlarged view of a sealing step in the manufacturing method example of the heat sink of the present disclosure. FIG. 22 is a partially enlarged view after the end of the sealing step in the manufacturing method example of the heat sink of the present disclosure.

The manufacturing method example of the heat sink of the present disclosure has a heat sink portion preparation step of preparing a heat sink portion 1′ including the base portion 20 to which the heat-generating element 100 is thermally connected and in which the internal spaces 23 extending the planar direction of the base portion 20 are provided, and the radiating fins 10 provided on the front surface of the base portion 20, a heat pipe insertion step of inserting the heat pipes 30 into the internal spaces 23 of the base portion 20, a plastic deformation step of fixing the heat pipes 30 inserted into the internal spaces 23 of the base portion 20 by plastically deforming the front surface of the base portion 20, and a sealing step of providing the sealing members 40 that seal each internal space 23 of the base portion 20 into the internal space 23 of the base portion 20 such that the sealing members 40 face the end portions 31, 32 of the fixed heat pipe 30 in longitudinal direction. A resin material charging step of charging the end portions 31, 32 of the heat pipe 30 in the longitudinal direction with the resin material 50 is included after the plastic deformation step and before the sealing step.

### Heat Sink Portion Preparation Step

As illustrated in FIG. 16A and FIG. 16B, in the heat sink portion preparation step, the heat sink portion 1′ including the base portion 20 in which the internal spaces 23 extending in the planar direction of the base portion 20 are provided, and the plurality of radiating fins 10, 10, 10 . . . erected on the first front surface 21 of the base portion 20 is prepared. In the heat sink portion 1′, the radiating fins 10 may be integrally formed with the base portion 20 or may be members that are bodies separate from the base portion 20. However, the heat sink portion 1′ in which the radiating fins 10 are integrally formed with the base portion 20 is preferred in terms of mechanical strength, thermally conductivity, reduction in the number of parts, ease of quality management, reduction of manufacturing cost, and the like. The internal spaces 23 of the heat sink portion 1′ are embedded in the base portion 20. Protruding parts 51 are provided on the first front surface 21 of the base portion 20. The heat sink portion 1′ can be obtained by extrusion-molding a metal material, for example.

### Heat Pipe Insertion Step

As illustrated in FIGS. 17 and 18, in the heat pipe insertion step, each heat pipe 30 is inserted into the internal space 23 from the one end 24 side to the other end 25 side of the internal space 23 of the base portion 20. The length of the heat pipe 30 is shorter than the length of the internal space 23, and the heat pipe 30 is positioned such that the heat pipe 30 exists in the central portion 26 of the internal space 23 and the heat pipe 30 does not exist in one end 24 and the other end 25 of the internal space 23. As illustrated in FIG. 18, before the plastic deformation step, the thickness of the base portion 20 in a part of the internal space 23 is T1′, and the dimension (the dimension in the radial direction) of the heat pipe 30 in a direction parallel to the thickness direction of the base portion 20 in a part of the internal space 23 is D1′.

### Plastic Deformation Step

As illustrated in FIG. 19, in the plastic deformation step, the base portion 20 is plastically deformed by pressing the protruding part 51 provided on the first front surface 21 of the base portion 20 to the heat pipe 30 inserted into the internal space 23 in the direction of the heat pipe 30 by a pressing jig (not shown). By plastically deforming the base portion 20 as described above, the heat pipe 30 is swage-processed to the internal space 23, and the heat pipe 30 is fixed to the internal space 23 of the base portion 20. As a result of the heat pipe 30 being fixed to the internal space 23 of the base portion 20, the heat pipe 30 is thermally connected to the base portion 20. As illustrated in FIG. 19, by plastically deforming the base portion 20 in the plastic deformation step, the thickness of the base portion 20 in the part in which the heat pipe 30 is fixed to the internal space 23 is reduced to T1 from T1′, and the dimension (the dimension in the radial direction) of the heat pipe in a direction parallel to the thickness direction of the base portion 20 is reduced to D1 from D1′. Therefore, in the heat sink 1, the thickness of the base portion 20 is T1, and the ratio of the dimension of the heat pipe 30 in the radial direction to the thickness of the base portion 20 is D1/T1. The protruding part 51 pressed in the direction of the heat pipe 30 by the pressing jig may remain on the first front surface 21 even after the pressing.

### Resin Material Charging Step

As illustrated in FIG. 20, in the resin material charging step, the end portions 31, 32 of the heat pipe 30 in the longitudinal direction are charged with the resin material 50 from one end 24 and the other end 25 of the internal space 23. Charging with the resin material 50 is performed such that the resin material 50 contacts the end portions 31, 32 of the heat pipe 30 in the longitudinal direction and fills the internal space 23 in the end portions 31, 32 of the heat pipe 30 in the longitudinal direction.

### Sealing Step

As illustrated in FIG. 21, in the sealing step, the sealing members 40 are press-fitted into the internal space 23 of the base portion 20 from one end 24 and the other end 25 of the internal space 23 so as to face the end portions 31, 32 of the heat pipe 30 in the longitudinal direction fixed to the internal space 23, and seal the internal space 23 of the base portion 20. As illustrated in FIG. 22, charging of the sealing member 40 into the internal space 23 is performed until the sealing member 40 contacts the resin material 50, and the resin material 50 is cured after the resin material 50 filling the internal space 23 exceeds the barb section of the end portion of the sealing member 40 on the heat pipe 30 side. As a result, the resin material 50 and the sealing member 40 can cause the internal space 23 to be airtight, and the heat sink 1 can be produced. When the sealing member 40 is metal and the material of the base portion 20 is also metal, the entire side surface of the base portion 20 is formed by metal. Therefore, when washing, painting, and the like are performed on the heat sink 1, the selection of the method of washing, painting, and the like can be simplified.

Next, other embodiments of the heat sink of the present disclosure will be described. In the heat sink of each of the abovementioned embodiments, the resin material is interposed between the end portion of the heat pipe in the longitudinal direction and the sealing member, but the internal space may simply be sealed with the sealing member without the resin material being interposed.

In the heat sink of each of the abovementioned embodiments, the shape of the base portion is a quadrilateral shape in planar view (in a state visually recognized from a position facing the radiating fins). However, the shape of the base portion can be selected, as appropriate, in accordance with the conditions of use and the like of the heat sink, and may be a shape having a bending portion, a shape having a cut-out portion, and the like in planar view.

The heat sink of the present disclosure can prevent corrosion from occurring in a part in which the container of the heat pipe and the base portion contact each other due to moisture such as rainwater and humidity and is excellent in weather resistance, and hence particularly has high utility value in a field of cooling a heat-generating element mounted on a device installed outdoors such as a communication device.

What is claimed is:

1. A heat sink, comprising:
a base portion to which a heat-generating element is thermally connected;
a radiating fin provided on a front surface of the base portion;
a heat pipe that is provided in an internal space of the base portion and stretches in a planar direction of the base portion; and
a sealing member that is provided in the internal space of the base portion so as to face an end portion of the heat pipe in a longitudinal direction and seals the internal space of the base portion.

2. The heat sink according to claim 1, wherein a resin material is further interposed between the end portion of the heat pipe in the longitudinal direction and the sealing member.

3. The heat sink according to claim 1, wherein the internal space of the base portion is a hole portion that extends in the planar direction of the base portion, and the heat pipe is inserted into the hole portion.

4. The heat sink according to claim 2, wherein the internal space of the base portion is a hole portion that extends in the planar direction of the base portion, and the heat pipe is inserted into the hole portion.

5. The heat sink according to claim 2, wherein a space between the end portion of the heat pipe in the longitudinal direction and the sealing member is filled with the resin material.

6. The heat sink according to claim 2, wherein a space between a part of a circumferential surface of the heat pipe and an inner surface of the internal space of the base portion is filled with the resin material.

7. The heat sink according to claim 5, wherein a space between a part of a circumferential surface of the heat pipe and an inner surface of the internal space of the base portion is filled with the resin material.

8. The heat sink according to claim 1, wherein the heat pipe is fixed to the internal space of the base portion by plastically deforming the base portion.

9. The heat sink according to claim 1, wherein a material of the base portion is different from a material of a container of the heat pipe.

10. The heat sink according to claim 1, wherein the sealing member is metal, and a material of the sealing member is in common with a material of the base portion.

11. The heat sink according to claim 1, wherein a protruding part is provided on the front surface of the base portion.

12. The heat sink according to claim 2, wherein a protruding part is provided on the front surface of the base portion.

13. The heat sink according to claim 1, wherein the heat pipe has a section that stretches in a planar direction of the radiating fin.

14. The heat sink according to claim 1, wherein the radiating fin includes a plurality of radiating fins parallelly arranged on the front surface of the base portion, and the heat pipe has a section that stretches in an array direction of the plurality of radiating fins.

15. The heat sink according to claim 1, wherein the radiating fin is provided on the front surface or a second front surface of the base portion, the second front surface is a planar surface facing the front surface.

16. The heat sink according to claim 1, wherein the radiating fin is provided on the front surface and a second front surface of the base portion, the second front surface is a planar surface facing the front surface.

17. The heat sink according to claim 1, wherein a ratio of a dimension of the heat pipe in a radial direction to a thickness of the base portion is 0.009 or more and 0.800 or less.

18. The heat sink according to claim 1, wherein a thickness of the base portion is 8.0 mm or more and 500 mm or less.

19. The heat sink according to claim 1, further having a region in which a fin pitch of a plurality of the radiating fins provided on the front surface of the base portion differs.

20. The heat sink according to claim 1, wherein the heat pipe is included in a plurality of heat pipes provided in the longitudinal direction of the heat pipe.
